(19) United States
(12) Patent Application Publication
(10) Pub. No.: US 2026/0351926 A1
(43) Pub. Date: Nov. 5, 2026

(54) SURFACE EMITTER AND METHOD FOR MANUFACTURING A SURFACE EMITTER

(71) Applicant: ams-OSRAM International GmbH, Regensburg (DE)

(72) Inventors: Ralph WIRTH, Lappersdorf (DE); Martin Rudolf BEHRINGER, Regensburg (DE)

(21) Appl. No.: 19/486,408

(22) PCT Filed: Aug. 27, 2024
(86) PCT No.: PCT/EP2024/073908

§ 371 Date: Nov. 21, 2025

(30) Foreign Application Priority Data
Sep. 21, 2023 (DE) 10 2023 125 625.4

(51) Int. Cl. H01S 5/183; H01S 5/068

(52) U.S. Cl. CPC H01S 5/18386; H01S 5/06821; H01S 5/18369

(57) ABSTRACT

A surface emitter and a method for manufacturing a surface emitter are disclosed, wherein the surface emitter comprises, in one embodiment: a substrate; a first mirror structure and a second mirror structure arranged above the substrate; a light-emitting structure arranged between the first mirror structure and the second mirror structure, wherein the light-emitting structure is configured to emit light, and wherein the first mirror structure and the second mirror structure are configured to reflect light emitted from the light-emitting structure; and a grating structure including a plurality of periodically arranged grating elements embedded in the substrate, wherein the grating structure is configured for polarization stabilization of the emitted light.

### CROSS-REFERENCE TO RELATED APPLICATIONS

This application is a national phase of International Application No. PCT/EP2024/073908 filed on Aug. 27, 2024, which claims priority to German Patent Application No. 10 2023 125 625.4, which was filed on Sep. 21, 2023, the entire contents of both of which are incorporated herein by reference.

### TECHNICAL AREA

Various embodiments relate to a surface emitter (vertical cavity surface emitting laser, VCSEL) and a method for manufacturing the same.

### BACKGROUND

Surface emitters can serve as light sources for a wide variety of applications in numerous fields, such as point emitters for biometric facial recognition in smartphones, security systems, etc. A surface emitter is a laser diode in which light is emitted perpendicular to the plane of the semiconductor chip. In a surface emitter, a light-emitting active region formed by epitaxial growth is typically arranged vertically between two Bragg mirrors (distributed Bragg reflector, DBR).

Various applications of surface emitters can be polarization-sensitive, such as timers, gyroscopes, magnetometers, optical mice, etc. For these applications, stable, linear polarization of the light emitted by the surface emitter may be necessary and/or desirable. However, even small changes in the operating conditions of the surface emitter can cause an abrupt polarization switch from a polarization state oriented in a first direction to a polarization state oriented in a second direction (orthogonal) opposite to the first direction, for example due to changes in modal gain, phase anisotropy in the presence of birefringence, the occurrence of higher-order transverse modes, etc.

### SUMMARY

Various aspects relate to a surface emitter and a method for manufacturing the same, which stabilize the polarization of the emitted light in order to prevent polarization switching, for example.

This is enabled, for example, by the surface emitter having an embedded grating structure which is designed to stabilize the polarization of the emitted light. In some embodiments, the grating structure may be embedded in a substrate of the surface emitter (outside an optical cavity of the surface emitter). In this way, polarization switching can be prevented, for example, in a rear side-emitting surface emitter. In other embodiments, the grating structure may be embedded in an epitaxial layer arranged within the optical cavity. In this way, inherent polarization stabilization can be achieved, for example.

In general, a surface emitter can have a plurality of epitaxial layers arranged one above the other (e.g., as part of the light-emitting active region or one of the Bragg mirrors). To manufacture such an epitaxial layer, it may be necessary for the underlying layer to also be an epitaxial layer. According to various aspects, it has been recognized that a grating structure can be arranged below the optical cavity or within the optical cavity if it is or becomes embedded in an epitaxial layer. In this way, a grating structure can be used for polarization stabilization for both rear side-emitting surface emitters and top side-emitting surface emitters. For example, the grating structure can also be used when one side of the substrate opposite the optical cavity is structured (e.g., into a three-dimensional (3D) lens). The surface emitter described herein for can, example, enable polarization stabilization in a temperature range from approximately −40 °C to approximately 150 °C (or even a wider temperature range). Embedding the grating structure in an epitaxial layer can ensure epitaxial growth of a layer formed thereon. Illustratively, embedding the grating structure, as compared to forming the grating structure in between two other layers, can improve the properties (dependent on the epitaxial growth of the layers) of the surface emitter.

### BRIEF DESCRIPTION OF THE DRAWINGS

In the drawings, the same reference numerals generally refer to the same parts in the different views. The drawings are not necessarily to scale, the emphasize being generally on illustrating the principles of the invention. In the following description, various aspects of the invention are described with reference to the following drawings, in which:

FIG. 1A to FIG. 1F each show a schematic cross-sectional view of a surface emitter according to various aspects;

FIG. 2A to FIG. 2C each show an exemplary embodiment of a grating structure according to various aspects;

FIG. 3 shows a flowchart of a method for manufacturing a surface emitter according to various aspects;

FIG. 4 shows a flowchart of a method for manufacturing a surface emitter according to various aspects; and

FIG. 5 shows schematic cross-sectional views in the manufacturing process of a surface emitter according to various aspects.

### DETAILED DESCRIPTION

The following detailed description refers to the accompanying drawings, which illustrate specific details and aspects in which the disclosure may be practiced. Various aspects are described with respect to a surface emitter, and various aspects are described with respect to a method for manufacturing a surface emitter. It is understood that aspects described in connection with the method may also apply to the surface emitter and vice versa. In the drawings, the same or similar elements, features, and structures are represented by the same reference numerals. It should be noted that the drawings serve to illustrate various aspects of the surface emitter and its manufacture and are not necessarily drawn to scale.

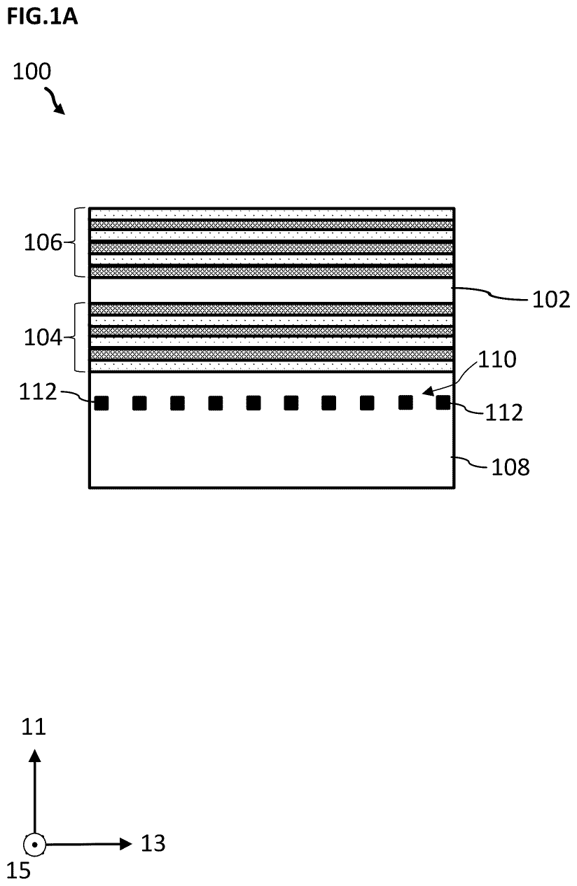

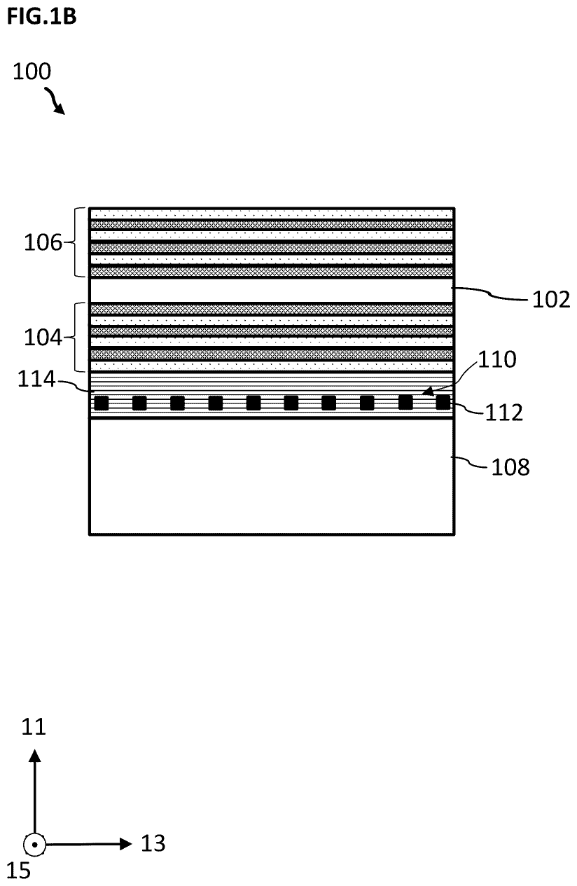

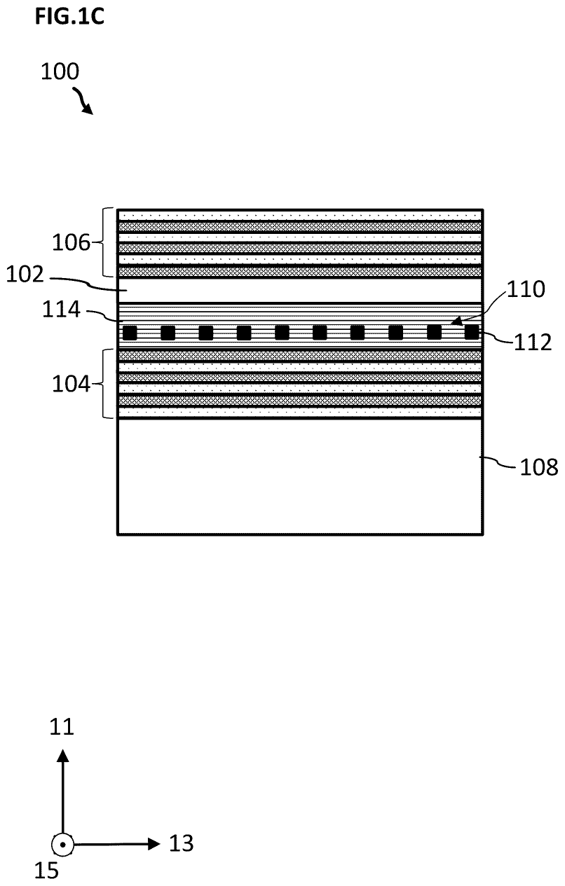

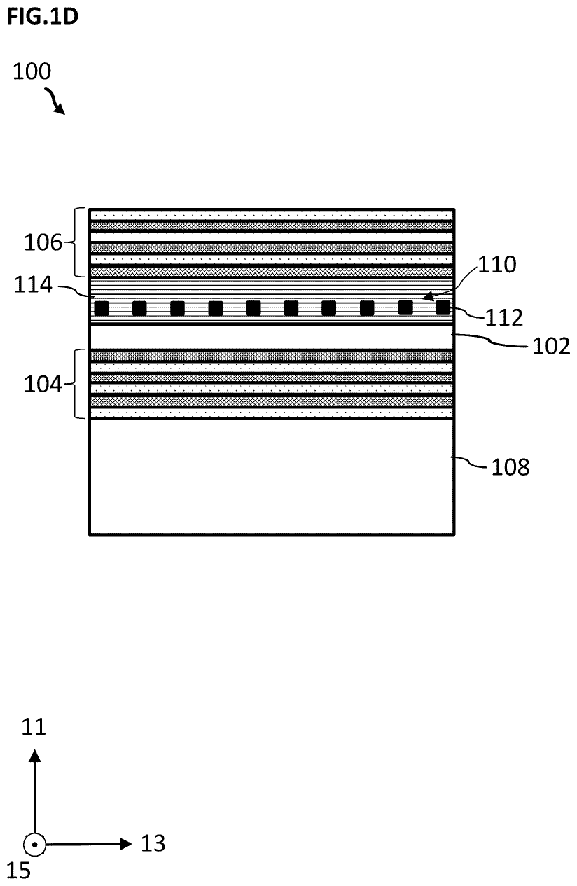

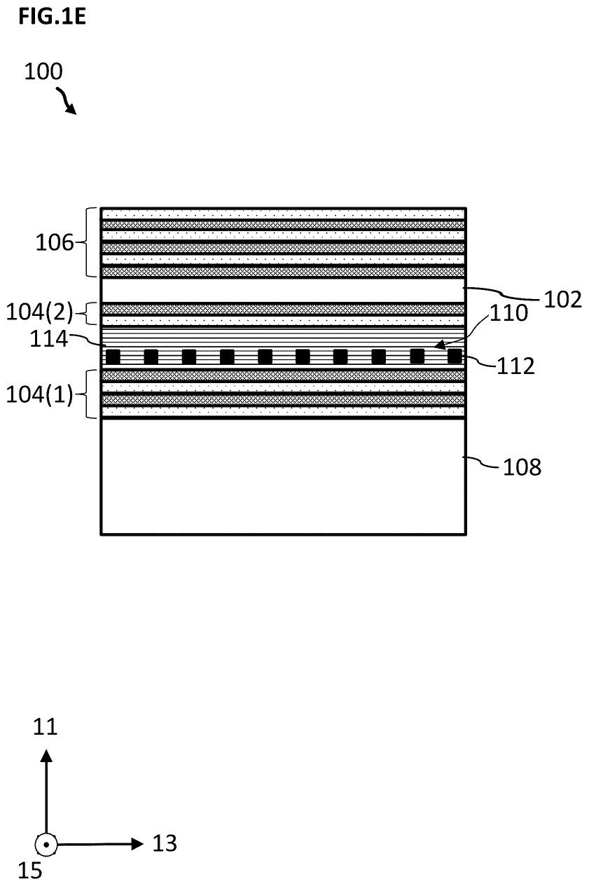

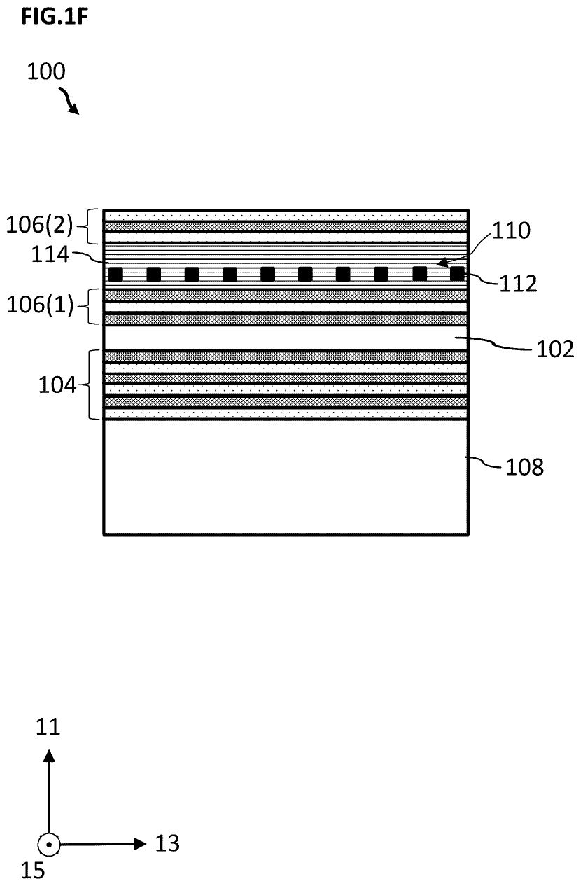

FIG. 1A to FIG. 1F each show a schematic cross-sectional view of a surface emitter 100 according to various aspects. In general, the surface emitter 100 may include a light-emitting structure 102 that may be disposed between a first (e.g., dielectric) mirror structure 104 and a second (e.g., dielectric) mirror structure 106. The light-emitting structure 102 may be configured to emit light (e.g., toward the first mirror structure 104 or the second mirror structure 106). The first mirror structure 104 and the second mirror structure 106 may be configured to reflect the light emitted by the light-emitting structure 102. The first mirror structure 104 and/or the second mirror structure 106 may each include a Bragg mirror or may be formed as a Bragg mirror. For example, the first mirror structure 104 and the second mirror structure 106 may be configured as a distributed Bragg reflector (DBR).

The surface emitter 100 described herein may be a top side-emitting surface emitter (top emitting VCSEL) or a rear side-emitting surface emitter (backside emitting VCSEL). This may define an emission direction of the surface emitter 100. In this case, the first mirror structure 104 and the second mirror structure 106 may have a (slightly) lower reflectivity than the other. For example, the first mirror structure 104 may have a first reflectivity and the second mirror structure 106 may have a second reflectivity that differs from the first reflectivity. In one example, the second reflectivity may be smaller so that light emitted in the direction of the first mirror structure 104 is reflected at this structure in the direction of the second mirror structure 106, and part of the light may pass through the second mirror structure 106 and thus be coupled out of the surface emitter 100.

The light-emitting structure 102 may include one or more epitaxially grown layers. For example, the light-emitting structure 102 may be formed as a stack of epitaxially grown layers. The light-emitting structure 102, which is designed to emit light, may also be referred to as an active structure and/or an active area.

The first mirror structure 104, the light-emitting structure 102, and the second mirror structure 106 may form an optical cavity. The optical cavity may be arranged such that the surface emitter 100 emits light of a predetermined frequency.

The light-emitting structure 102 may include quantum wells for generating the light. A quantum well can be understood as a potential profile that limits the freedom of motion of a particle in one spatial dimension (e.g., perpendicular to an extension of the light-emitting structure 102), whereby the particle can only assume discrete (potential) energy values. This can be achieved, for example, by arranging a semiconductor layer with a first band gap between two other semiconductor layers with a second band gap, wherein the first band gap is smaller than the second band gap.

At least part of the light emitted by the surface emitter 100 may be coherent. The emission color of the light emitted by the surface emitter 100 may depend on the design of the light-emitting structure 102. Thus, the emission color of the emitted light can be adjusted during manufacturing. A wavelength of the emitted light may generally have electromagnetic radiation in the non-visible spectrum (e.g., in the ultraviolet spectrum, UV, or in the infrared range, IR) or in the visible spectrum (e.g., red, green, or blue). The light-emitting structure 102 may have a suitably appropriate opto-electronic III/V or II/VI semiconductor material system, such as an aluminum gallium nitride/indium gallium nitride (AlGaN/InGaN) material system for blue light, green light, and/or ultraviolet light, an aluminum gallium arsenide/indium gallium aluminum arsenide (AlGaAs/InGaAlAs) material system for infrared light, an aluminum gallium indium phosphide (AlGaInP) material system for red light, etc.

As described herein, the first mirror structure 104 and the second mirror structure 106 may be configured to reflect the light emitted from the light-emitting structure 102. According to various aspects, the first mirror structure 104 and/or the second mirror structure 106 may each have multiple (e.g., alternating) (dielectric) mirror layers with different refractive indices (which are, for example, configured as Bragg mirrors). For example, the first mirror structure 104 may have a plurality of first mirror layers (e.g., a number N of first mirror layers (where N is an integer greater than or equal to two)), and the second mirror structure 106 may have a plurality of second mirror layers (e.g., mirror layer pairs) (e.g., a number M of second mirror layers (where M is an integer greater than or equal to two). The thickness of the mirror layers can, for example, be approximately one quarter of the wavelength, λ, of the emitted light.

The surface emitter 100 can be electrically contactable vertically, for example with contacts on opposite sides of the active area (i.e., the light-emitting structure 102), or horizontally, for example with contacts on a common side. According to various aspects, the light-emitting structure 102 may be arranged (vertically) between at least one n-contact layer (e.g., an n-doped semiconductor layer) and at least one p-contact layer (e.g., a p-doped semiconductor layer) (and, for example, in immediate contact with these).

A contact layer described herein (e.g., the n-contact layer and/or the p-contact layer) may be configured to electrically contact the light-emitting structure 102. For example, the contact layer may be formed from a light-transmissive (i.e., transparent to the light emitted by the light-emitting structure 102) conductive material, such as a transparent conductive oxide (TCO), for example indium tin oxide (ITO). Alternatively, or additionally, the contact layer may be formed as or include a tunnel electrode.

The p-contact layer and/or the n-contact layer may be arranged such that at least a portion of the light-emitting structure 102 is exposed, so that an aperture (opening) is formed. This (electrical and/or optical) aperture can enable beam shaping of the surface emitter 100 perpendicular to an extension of the light-emitting structure 102.

The surface emitter 100 may include a substrate 108. The first mirror structure 104, the light-emitting structure 102, and the second mirror structure 106 may be arranged (e.g., in this order) above the substrate 108. The first mirror structure 104, the light-emitting structure 102, and/or the second mirror structure 106 may be arranged substantially parallel to a surface of the substrate 108. The substrate 108 may, for example, include or be a (semiconductor) wafer (also referred to as a carrier wafer in some aspects). For example, the wafer may be made of gallium arsenide. Optionally, a buffer layer may be arranged between the substrate 108 and the first mirror structure 104. In some embodiments, the buffer layer may also be part of the substrate 108 (i.e., the substrate 108 may include the buffer layer). In various embodiments, the buffer layer may consist of gallium arsenide. Optionally, the substrate 108 (e.g., on its surface facing the light-emitting structure 102) may have one or more other (e.g., epitaxially grown) structures (e.g., layer or layer stack), such as a photodiode set up for monitoring.

The light emitted by the surface emitter 100 in the direction of emission may be linearly polarized. A polarization direction of the light may be substantially perpendicular (to the direction of propagation of the light). The surface emitter 100 may have a grating structure 110. The grating structure 110 may be configured for polarization stabilization of the emitted light. The grating structure 110 may have a plurality of periodically arranged grating elements 112.

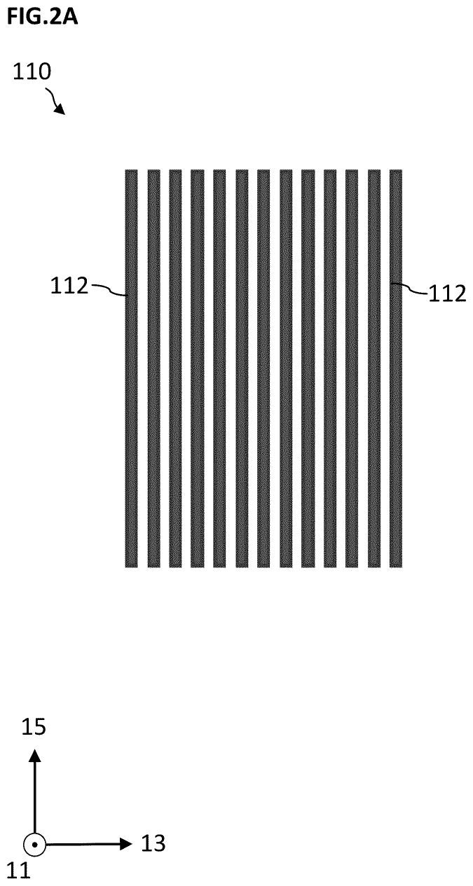

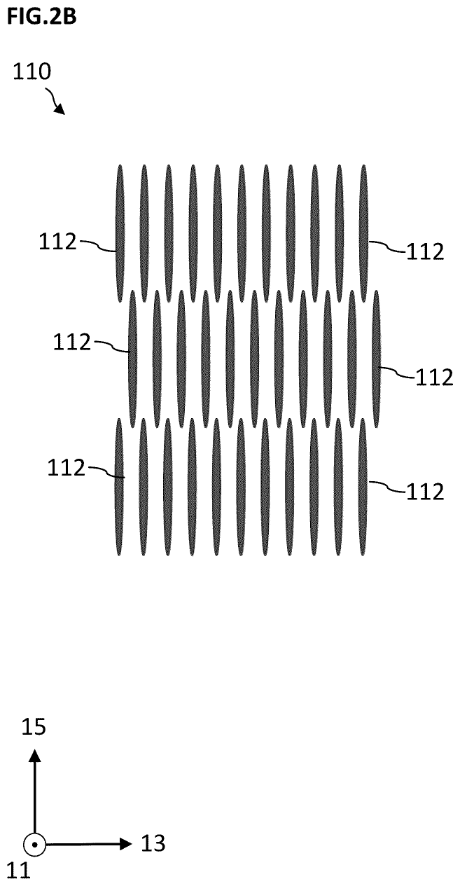

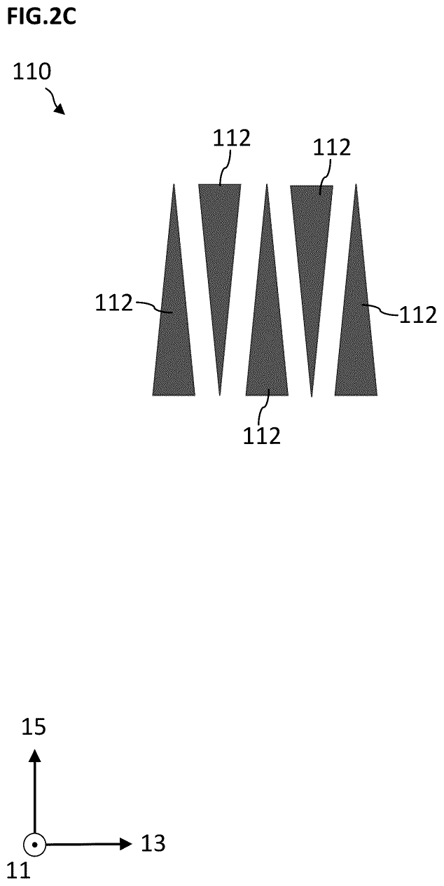

A grating structure as described herein may be understood to be a regular arrangement of (e.g., uniformly spaced) grating elements. Exemplary embodiments of the grating structure 110 are shown in FIG. 2A to FIG. 2C. The grating elements 112 of the grating structure 110 may, for example (see FIG. 2A), include a plurality of lines arranged side by side so that the light emitted by the light-emitting structure 102 can pass through a space between adjacent lines of the grating structure 110. It is understood that these are exemplary embodiments of the grating structure 110 and that the grating structure 110 may also have any other arrangement of grating elements 112 in order to break the (rotational) symmetry of the surface emitter resonator and/or the polarization-independent reflectivity of the first mirror structure 104 and/or second mirror structure 106.

As described herein, the substrate 108 may be a wafer, or a wafer may include the substrate 108. According to various aspects, a plurality of surface emitters 100 may be arranged on the substrate 108. In some aspects, the grating structure 110 may be formed along an entire surface of the wafer. In other aspects, the grating structure 110 may be arranged exclusively in the areas where a respective surface emitter 100 is formed.

The grating structure 110 (e.g., each grating element of the plurality of periodically arranged grating elements 112) may include or consist of a material having a refractive index that is at least 0.1 (e.g., at least 0.5, e.g., at least 1.0) greater (or smaller) than a refractive index of the first mirror structure 104 and/or the second mirror structure 106. A refractive index of a mirror structure may be an average refractive index.

According to various aspects, the grating structure 110 may include or consist of a dielectric material, such as silicon oxide (SiO₂), silicon nitride (SiₓN_{y}), aluminum oxide (Al₂O₃) or titanium oxide (TiO₂). In other embodiments, the grating structure 110 may include or consist of a semimetal. In yet other embodiments, the grating structure 110 may include or consist of a semiconductor material or a semimetal.

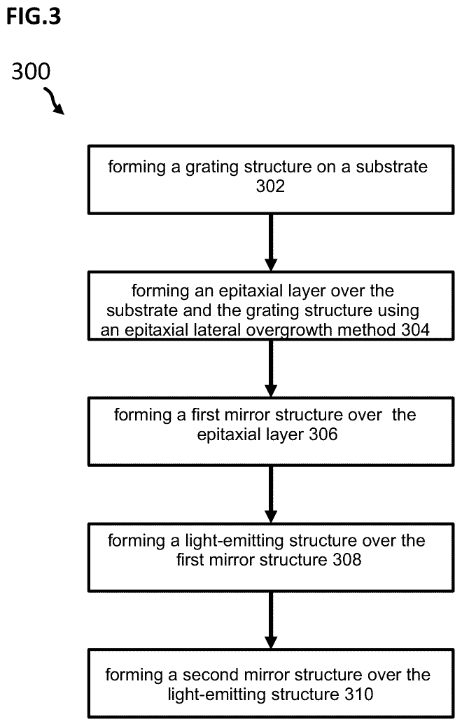

As shown in FIG. 1A, the grating structure 110 may, for example, be embedded in the substrate 108. Consequently, the grating structure 110 may be completely surrounded by the substrate 108. An exemplary method 300 for embedding the grating structure 110 in the substrate 108 is described with reference to FIG. 3.

In this case, a distance between two adjacent grating elements of the plurality of periodically arranged grating elements 122 may be in a range from approximately

$$0 , 1 \cdot \frac{λ}{4}$$

to approximately 10·λ (where λ is the wavelength of the emitted light). A thickness of each grating element of the plurality of periodically arranged grating elements 112 may be in a range from approximately 0,01·λ to approximately 10·λ.

As shown in FIG. 1B to FIG. 1F, the grating structure 110 (e.g., the plurality of periodically arranged grating elements 112) may be embedded in an epitaxial layer 114.

In some embodiments, the epitaxial layer 114 may be disposed outside the optical cavity, e.g., between the substrate 108 and the first mirror structure 104 (see FIG. 1B) (and optionally in immediate physical contact therewith). Alternatively, the epitaxial layer 114 may be arranged above (e.g., immediately on) the second mirror structure 106.

The arrangement of the grating structure 112 outside the optical cavity may, for example, be particularly advantageous for a rear side-emitting surface emitter 100, since in this case the reflectivity of the first mirror structure 104 is lower than the reflectivity of the second mirror structure 106 and thus the influence of the grating structure 110 through the first mirror structure 104 is stronger, thereby enhancing polarization stabilization.

In other embodiments, the epitaxial layer 114 may be disposed within the optical cavity. In a first example, the epitaxial layer 114 may be disposed between (and optionally in immediate physical contact with) the first mirror structure 104 and the light-emitting structure 102 (see FIG. 1C). In a second example, the epitaxial layer 114 may be disposed between (and optionally in immediate physical contact with) the light-emitting structure 102 and the second mirror structure 106 (see FIG. 1D). In a third example, the epitaxial layer 114 may be arranged between (and optionally in immediate physical contact with) two consecutive mirror layers of the plurality of mirror layers of the first mirror structure 104 (see FIG. 1E). Illustratively, a first portion 104(1) of the plurality of mirror layers may be arranged with a number of N-x mirror layers below the first mirror structure 104, and a second portion 104(2) of the plurality of mirror layers may be arranged with a number of x mirror layers above the first mirror structure 104 (where x is greater than or equal to one, e.g., in FIG. 1E, N=6 and x=2). In a fourth example, the epitaxial layer 114 may be arranged between (and optionally in immediate physical contact with) two consecutive mirror layers of the plurality of mirror layers of the second mirror structure 106 (see FIG. 1F). Illustratively, a first portion 106(1) of the plurality of mirror layers may be arranged with a number of M-y mirror layers below the second mirror structure 106, and a second portion 106(2) of the plurality of mirror layers may be arranged with a number of y mirror layers above the second mirror structure 106 (wherein y is greater than or equal to one, e.g., in FIG. 1F, M=6 and y=3).

According to various aspects (e.g., when the grating structure 110 is arranged in the optical cavity), a distance d between two adjacent grating elements of the plurality of periodically arranged grating elements 122 may correspond approximately to an integer multiple of a quarter wavelength of the emitted light (

$$d = p \cdot \frac{λ}{4} ,$$

where p is an integer greater than or equal to one). In order to ensure the properties of the surface emitter 100, it may be necessary, for example, if the grating structure 110 is arranged in the optical cavity, that a defect density (at least in a surface region) of the epitaxial layer 114 is less than 1·10⁹ cm⁻² (e.g., less than 1·10⁷ cm⁻², e.g., less than 1·10⁵ cm⁻²). This can be achieved, for example, by the method described herein using epitaxial lateral overgrowth. The defect density may indicate a number of defects per square centimeter.

According to various aspects, the epitaxial layer 114 described herein may consist of a semiconductor material.

FIG. 3 shows a flowchart of a method 300 for manufacturing a surface emitter (e.g., the surface emitter 100 according to the embodiment shown in FIG. 1A) according to various aspects.

The method 300 may include (in 302) forming a grating structure (immediately) on a substrate. The grating structure may include a plurality of periodically arranged grating elements.

The method 300 may (in 304) include forming an epitaxial layer over the substrate and the grating structure using an epitaxial lateral overgrowth method. In this way, the plurality of periodically arranged grating elements of the grating structure can be embedded. Here, the substrate and the epitaxial layer can consist of the same material. This allows the grating structure to be embedded in the substrate.

The method 300 may (in 306) include forming a first mirror structure over (e.g., immediately on) the epitaxial layer.

The method 300 may (in 308) include forming a light-emitting structure over (e.g., immediately on) the first mirror structure. The light-emitting structure may be configured to emit light.

The method 300 may (in 310) include forming a second mirror structure over (e.g., immediately on) the light-emitting structure. The first mirror structure and the second mirror structure may be configured to reflect the light emitted by the light-emitting structure.

The grating structure may be configured for polarization stabilization of the emitted light.

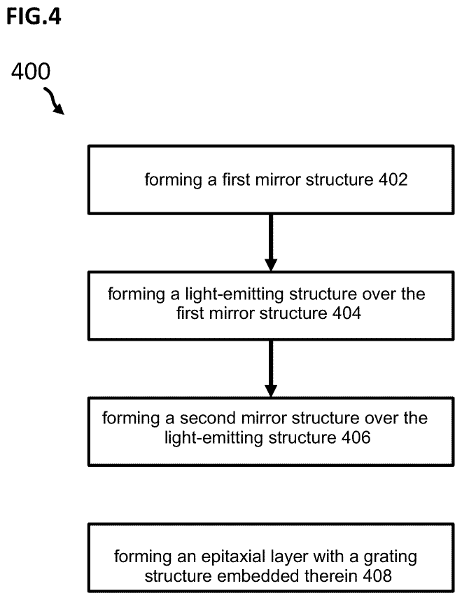

FIG. 4 shows a flowchart of a method 400 for manufacturing a surface emitter (e.g., the surface emitter 100 according to one of the embodiments shown in FIG. 1B to FIG. 1F) according to various aspects.

The method 400 may include (in 402) forming a first mirror structure.

The method 400 may (in 404) include forming a light-emitting structure over the first mirror structure. The light-emitting structure may be configured to emit light.

The method 400 may (in 406) include forming a second mirror structure over the light-emitting structure. The first mirror structure and the second mirror structure may be configured to reflect light emitted by the light-emitting structure.

The method 400 may (in 408) include forming an epitaxial layer with a grating structure embedded therein. The grating structure may include a plurality of periodically arranged grating elements and may be configured for polarization stabilization of the emitted light.

As described above with respect to the surface emitter 100, the epitaxial layer with the grating structure embedded therein may be disposed outside the optical cavity or inside the optical cavity.

The epitaxial layer can thus be formed:
between the light-emitting structure and the first mirror structure, or
between the light-emitting structure and the second mirror structure, or
between two of the multiple layers of the first mirror structure, or
between two of the multiple layers of the second mirror structure, or
between the substrate and the first mirror structure, or
above (e.g., immediately on) the second mirror structure.

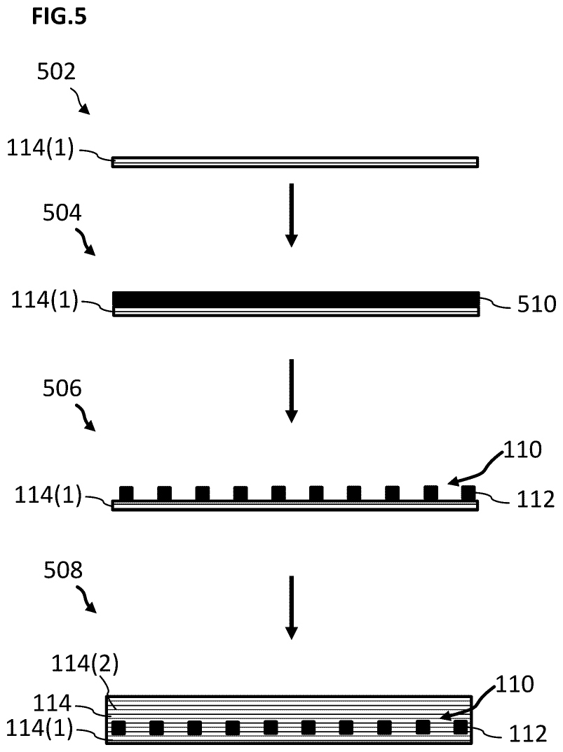

FIG. 5 shows schematic cross-sectional views in the manufacturing process of the embedded grating structure 110 according to various aspects.

Thus, (in 502), a first layer can be formed using an epitaxial process as a first portion 114(1) of the epitaxial layer 114. Alternatively, this portion 114(1) can be part of the substrate 108.

Subsequently (in 504 and 506), the grating structure 110 can be formed (e.g., immediately on) the first portion 114(1) of the epitaxial layer 114. For example, as shown in FIG. 5, a layer 510 can be formed on the first portion 114(1) of the epitaxial layer 114 (in 504) and then (in 506), for example, using photolithography in conjunction with (wet and/or dry) etching, this layer 510 can be structured into the grating structure 110. Alternatively, a (e.g., photolithographic) mask with multiple openings can first be applied, and the grating structure 110 can be formed by coating the mask and then removing the mask (in the openings).

Subsequently, a second layer can be formed (in 508) as a second portion 114(2) of the epitaxial layer 114 over the first layer and the grating structure 110 using an epitaxial lateral overgrowth (ELOG) process. It is understood that the first portion 114(1) and the second portion 114(2) of the epitaxial layer 114 may consist of the same materials. In this way, the grating structure 110 can be embedded in the epitaxial layer 114.

Various examples are provided below that describe one or more aspects of the surface emitter 100 and the method. It is understood that aspects described in relation to the surface emitter 100 may also apply to the method of manufacturing it, and vice versa. For example, elements of the surface emitter 100 may be formed in a corresponding manufacturing process.
Example 1 is a surface emitter including: a substrate; a first mirror structure and a second mirror structure arranged above the substrate; a light-emitting structure arranged (vertically) between the first mirror structure and the second mirror structure, wherein the light-emitting structure is configured to emit light, and wherein the first mirror structure and the second mirror structure are configured to reflect the light emitted by the light-emitting structure; and a grating structure including a plurality of periodically arranged grating elements embedded in the substrate, wherein the grating structure is configured for polarization stabilization of the emitted light.
Example 2 is configured according to Example 1, wherein the substrate includes a base substrate and an epitaxial substrate layer, wherein the base substrate and the epitaxial substrate layer are made of the same material, and wherein the plurality of periodically arranged grating elements are embedded between the base substrate and the epitaxial substrate layer.
Example 3 is configured according to Example 1 or 2, wherein a distance between two adjacent grating elements of the plurality of periodically arranged grating elements is in a range of approximately

$$0 , 1 \cdot \frac{λ}{4}$$

to approximately 10·λ, wherein A is the wavelength of the emitted light.
Example 4 is configured according to one of Examples 1 to 3, wherein a thickness of each grating element of the plurality of periodically arranged grating elements is in a range of approximately 0,01·λ to approximately 10·λ, wherein λ is the wavelength of the emitted light.
Example 5 is a surface emitter including: a first mirror structure and a second mirror structure; a light-emitting structure disposed (vertically) between the first mirror structure and the second mirror structure, wherein the light-emitting structure is configured to emit light, and wherein the first mirror structure and the second mirror structure are configured to reflect the light emitted from the light-emitting structure; an epitaxial layer; and a grating structure including a plurality of periodically arranged grating elements embedded in the epitaxial layer, wherein the grating structure is configured for polarization stabilization of the emitted light.
Example 6 is configured according to Example 5, wherein the epitaxial layer is arranged between the light-emitting structure and the first mirror structure; or wherein the epitaxial layer is arranged between the light-emitting structure and the second mirror structure.
Example 7 is configured according to Example 5, wherein the second mirror structure is arranged above the first mirror structure and wherein the epitaxial layer is arranged above (e.g., immediately on) the second mirror structure.
Example 8 is configured according to Example 5, wherein the first mirror structure includes multiple mirror layers and wherein the epitaxial layer is arranged between two of the multiple mirror layers of the first mirror structure; or wherein the second mirror structure includes multiple mirror layers and wherein the epitaxial layer is arranged between two of the multiple mirror layers of the second mirror structure.
Example 9 is configured according to Example 5, wherein the second mirror structure is arranged above the first mirror structure and wherein the epitaxial layer is arranged between a substrate and the first mirror structure.
Example 10 is configured according to one of Examples 1 to 9, wherein a distance between two adjacent grating elements of the plurality of periodically arranged grating elements corresponds approximately to an integer multiple of a quarter wavelength of the emitted light.
Example 11 is configured according to one of examples 1 to 10, wherein the epitaxial layer has a defect density (as a number of defects) of less than 1·10⁹ cm⁻² (e.g., less than 1·10⁷ cm⁻², e.g., less than 1·10⁵ cm⁻²).
Example 12 is configured according to one of examples 1 to 11, wherein the grating structure has (e.g., consists of) a material whose refractive index is at least 0.1 (e.g., at least 0.5, preferably at least 1) greater or less than a refractive index of the first mirror structure and/or the second mirror structure.
Example 13 is configured according to one of examples 1 to 12, wherein the grating structure includes or consists of a dielectric material (e.g., silicon oxide, silicon nitride, aluminum oxide, or titanium oxide), a semimetal, or a semiconductor material.
Example 14 is configured according to one of examples 1 to 13, wherein the first mirror structure and the second mirror structure include a Bragg mirror respectively.
Example 15 is a method for manufacturing a surface emitter, the method including: forming a grating structure (immediately) on a substrate, wherein the grating structure includes a plurality of periodically arranged grating elements; forming an epitaxial layer over the substrate and the grating structure using an epitaxial lateral overgrowth method to embed the plurality of periodically arranged grating elements of the grating structure; and forming a first mirror structure over the epitaxial layer; forming a light-emitting structure over the first mirror structure, the light-emitting structure being configured to emit light; and forming a second mirror structure over the light-emitting structure, the first mirror structure and the second mirror structure being configured to reflect the light emitted by the light-emitting structure; wherein the grating structure is configured for polarization stabilization of the emitted light.
Example 16 is configured according to Example 15, wherein the substrate and the epitaxial layer are made of the same material.
Example 17 is configured according to Example 15 or 16, wherein the grating structure is formed such that a distance between two adjacent grating elements of the plurality of periodically arranged grating elements is in a range of approximately

$$0 , 1 \cdot \frac{λ}{4}$$

to approximately 10·λ, wherein λ is the wavelength of the emitted light.
Example 18 is configured according to one of examples 15 to 17, wherein the grating structure is formed such that a thickness of each grating element of the plurality of periodically arranged grating elements is in a range of approximately 0,01·λ to approximately 10·λ, wherein λ is the wavelength of the emitted light.
Example 19 is a method for manufacturing a surface emitter, the method including: forming a first mirror structure; forming a light-emitting structure over the first mirror structure, wherein the light-emitting structure is configured to emit light; forming a second mirror structure over the light-emitting structure, wherein the first mirror structure and the second mirror structure are configured to reflect the light emitted from the light-emitting structure; and forming an epitaxial layer with a grating structure embedded therein, wherein the grating structure includes a plurality of periodically arranged grating elements and is configured for polarization stabilization of the emitted light.
Example 20 is configured according to Example 19, wherein forming of the epitaxial layer with the grating structure embedded therein includes: forming, as a first portion of the epitaxial layer, a first layer using an epitaxial process, forming the grating structure (immediately) on the first layer, and forming, as a second portion of the epitaxial layer, a second layer over the first layer and the grating structure using an epitaxial lateral overgrowth process to embed the plurality of periodically arranged grating elements of the grating structure.
Example 21 is configured according to Example 19 or 20, wherein the first layer and the second layer are made of the same material.
Example 22 is configured according to one of Examples 19 to 21, wherein the epitaxial layer is formed between the light-emitting structure and the first mirror structure; or wherein the epitaxial layer is formed between the light-emitting structure and the second mirror structure.
Example 23 is configured according to one of examples 19 to 21, wherein the second mirror structure is formed over the first mirror structure and wherein the epitaxial layer is formed over (e.g., immediately on) the second mirror structure.
Example 24 is configured according to one of examples 19 to 21, wherein the first mirror structure has multiple mirror layers and wherein the epitaxial layer is formed between two of the multiple mirror layers of the first mirror structure; or wherein the second mirror structure has multiple mirror layers and wherein the epitaxial layer is formed between two of the multiple mirror layers of the second mirror structure.
Example 25 is configured according to one of examples 19 to 21, wherein the second mirror structure is formed above the first mirror structure and wherein the epitaxial layer is formed between a substrate and the first mirror structure.
Example 26 is configured according to one of examples 15 to 25, wherein the grating structure is formed such that a distance between two adjacent grating elements of the plurality of periodically arranged grating elements corresponds approximately to an integer multiple of a quarter wavelength of the emitted light.
Example 27 is configured according to one of examples 15 to 26, wherein the epitaxial layer has a defect density (as a number of defects) of less than 1·10⁹ cm⁻² (e.g., less than 1·10⁷ cm⁻², e.g., less than 1·10⁵ cm⁻²).
Example 28 is configured according to one of examples 15 to 27, wherein the grating structure has (e.g., consists of) a material whose refractive index is at least 0.1 (e.g., at least 0.5, preferably at least 1) greater or less than a refractive index of the first mirror structure and/or the second mirror structure.
Example 29 is configured according to one of examples 15 to 28, wherein the grating structure includes or consists of a dielectric material (e.g., silicon oxide, silicon nitride, aluminum oxide, or titanium oxide), a semimetal, or a semiconductor material.
Example 30 is configured according to one of examples 15 to 29, wherein the first mirror structure and the second mirror structure include a Bragg mirror respectively.
Example 31 is configured according to one of examples 15 to 30, wherein forming the grating structure includes: forming a layer; and forming the grating structure by patterning the layer into the plurality of periodically arranged grating elements.
Example 32 is configured according to one of examples 15 to 30, wherein forming the grating structure includes: forming a mask having a plurality of openings according to the grating structure; and forming the grating structure by coating the mask and then removing the mask.
Example 33 is a control device including one or more processors configured to perform the method according to any one of examples 15 to 32.
Example 34 is a computer-readable medium (e.g., a computer program product, a non-transitory storage medium, a non-volatile storage medium, or a non-volatile storage medium) that stores instructions which, when executed by a processor, cause the processor to control an apparatus to perform a method according to any one of examples 15 to 32.

Various aspects relate to an epitaxial layer and/or forming an epitaxial layer. In general, an epitaxial layer can be formed on a crystalline substrate (e.g., another layer). An epitaxial layer can be understood to be a layer in which at least one crystallographic orientation of a single crystal of the epitaxial layer corresponds to an orientation of the crystalline substrate. In general, an epitaxial layer can be understood to be an essentially mono-crystalline layer. According to various aspects, an epitaxial layer described herein can be a layer that is mono-crystalline at least in the section that forms a surface emitter (e.g., surface emitter 100). Epitaxy can be analyzed (e.g., measured, confirmed) using X-ray diffraction (XRD) (non-destructive) and/or transmission electron microscopy (TEM), for example.

An epitaxial layer can generally be formed, for example, by a physical vapor deposition process, PVD (e.g., molecular beam epitaxy (MBE), sputtering, for example at a temperature above room temperature) and/or a chemical vapor deposition process, CVD (e.g., atomic layer deposition (ALD)). Such an epitaxial layer can therefore also be referred to as an epitaxially grown layer and/or an epitaxially formed layer.

A structure embedded in another structure (e.g., a layer) can be understood as a structure that is (completely) surrounded on all sides by the other structure (e.g., the layer). Thus, all (outer) surfaces of the structure can be adjacent to the other structure (e.g., in immediate contact with it).

A structure can be embedded in a layer, for example, using (e.g., by means of) an epitaxial lateral overgrowth (ELOG) process. In this case, a first portion of the layer can be formed using an epitaxial layer formation process. The structure can then be formed (immediately) on the first portion of the layer, and a second portion of the layer can then be formed on the exposed sections of the first portion of the layer and on the structure using the epitaxial lateral overgrowth process. In this way, the layer can, for example, be a substantially mono-crystalline epitaxial layer in which the structure is embedded. Epitaxial lateral overgrowth enables, for example, the defect density of the layer to be significantly lower compared to other layer manufacturing methods. One method of epitaxial lateral overgrowth is, for example, hydride vapor phase epitaxy (HVPE).

The word “exemplary” is used here to mean “as an example, instance, or illustration.” Any example or design described here as “exemplary” is not necessarily to be understood as preferred or advantageous over other examples or designs.

The term “processor” as used herein may be understood to mean any type of entity that allows the processing of data or signals. The data or signals may, for example, be handled according to at least one (i.e., one or more than one) specific function performed by the processor. A processor may include or be formed from an analog circuit, a digital circuit, a mixed-signal circuit, a logic circuit, a microprocessor, a central processing unit (CPU), a graphics processing unit (GPU), a digital signal processor (DSP), a field-programmable gate array (FPGA), an integrated circuit, or any combination thereof. Any other type of implementation of the respective functions, which are described in more detail below, can also be understood as a processor or logic circuit. It is understood that one or more of the process steps described in detail herein can be executed (e.g., implemented) by a processor through one or more specific functions performed by the processor. The processor may therefore be configured to perform one of the methods described herein or its components for information processing.

The words “plurality” and “multiple” in the description or claims expressly refer to a quantity greater than one.

The term “connected” can be understood in the sense of a (e.g., mechanical, optical, and/or electrical) connection and/or interaction, e.g., direct or indirect. For example, multiple elements may be mechanically connected to each other so that they are physically held together (e.g., a plug connected to a socket) and electrically connected so that they have an electrically conductive path (e.g., signal paths exist along a communicative chain).

In the above descriptions and accompanying figures, various components of the surface emitter are shown as separate elements, but discrete optical functions may also be implemented as a single element. Similarly, a single element may also be or become divided into two or more elements.

It is assumed that the methods described herein are exemplary and can therefore be implemented in a corresponding device. It is also assumed that implementations of the devices described herein can be implemented as a corresponding method.

Although the disclosure has been shown and described with reference to certain embodiments, it is understood that various amendments in form and detail may be made without departing from the scope of the disclosure as defined by the accompanying claims. The scope of the disclosure is therefore indicated by the appended claims, and all modifications falling within the meaning and scope of the claims are therefore included.

### REFERENCE NUMERAL LIST

100 surface emitter
102 light-emitting structure
104 first mirror structure
106 second mirror structure
108 substrate
110 grating structure
112 multitude of periodically arranged grating elements
114 epitaxial layer
114(1) first part of the epitaxial layer 114
114(2) second part of the epitaxial layer 114
300, 400 method for producing a surface emitter

What is claimed is:

1. A surface emitter comprising:
a substrate;
a first mirror structure and a second mirror structure arranged above the substrate;
a light-emitting structure arranged between the first mirror structure and the second mirror structure, wherein the light-emitting structure is configured to emit light, and wherein the first mirror structure and the second mirror structure are configured to reflect the light emitted by the light-emitting structure; and
a grating structure comprising a plurality of periodically arranged grating elements embedded in the substrate, wherein the grating structure is configured for polarization stabilization of the emitted light, wherein the grating structure comprises or consists of a dielectric material.

2. The surface emitter according to claim 1,
wherein a distance between two adjacent grating elements of the plurality of periodically arranged grating elements is in a range of approximately
$$0 , 1 \cdot \frac{λ}{4}$$
to approximately 10·λ, wherein λ is the wavelength of the emitted light; and/or
wherein a thickness of each grating element of the plurality of periodically arranged grating elements is in a range from approximately 0.01·λ to approximately 10·λ, wherein λ is the wavelength of the emitted light.

3. The surface emitter comprising:
a first mirror structure and a second mirror structure;
a light-emitting structure disposed between the first mirror structure and the second mirror structure, wherein the light-emitting structure is configured to emit light, and wherein the first mirror structure and the second mirror structure are configured to reflect the light emitted by the light-emitting structure;
an epitaxial layer; and
a grating structure comprising a plurality of periodically arranged grating elements embedded in the epitaxial layer, wherein the grating structure is configured for polarization stabilization of the emitted light, wherein the grating structure comprises or consists of a dielectric material.

4. The surface emitter according to claim 3,
wherein the epitaxial layer is arranged between the light-emitting structure and the first mirror structure; or
wherein the epitaxial layer is arranged between the light-emitting structure and the second mirror structure.

5. The surface emitter according to claim 3,
wherein the second mirror structure is arranged above the first mirror structure and wherein the epitaxial layer is arranged above the second mirror structure.

6. The surface emitter according to claim 3,
wherein the first mirror structure comprises multiple mirror layers and wherein the epitaxial layer is arranged between two of the multiple mirror layers of the first mirror structure; or
wherein the second mirror structure comprises multiple mirror layers, and wherein the epitaxial layer is arranged between two of the multiple mirror layers of the second mirror structure.

7. The surface emitter according to claim 3,
wherein the second mirror structure is arranged above the first mirror structure and wherein the epitaxial layer is arranged between a substrate and the first mirror structure.

8. The surface emitter according to claim 1,
wherein a distance between two adjacent grating elements of the plurality of periodically arranged grating elements corresponds to an integer multiple of a quarter wavelength of the emitted light.

9. The surface emitter according to claim 1,
wherein the epitaxial layer has a defect density of less than 1·10⁹ cm⁻² in at least one surface region.

10. The surface emitter according to claim 1,
wherein the grating structure comprises a material whose refractive index is at least 0.1 greater than or less than a refractive index of the first mirror structure and/or the second mirror structure.

11. The surface emitter according to claim 1,
wherein the first mirror structure and the second mirror structure comprise a Bragg mirror respectively.

12. A method for manufacturing a surface emitter, the method comprising:
forming a grating structure on a substrate, wherein the grating structure comprises a plurality of periodically arranged grating elements;
forming an epitaxial layer over the substrate and the grating structure using a method for epitaxial lateral overgrowth to embed the plurality of periodically arranged grating elements of the grating structure; and
forming a first mirror structure over the epitaxial layer;
forming a light-emitting structure over the first mirror structure, the light-emitting structure configured to emit light; and
forming a second mirror structure over the light-emitting structure, wherein the first mirror structure and the second mirror structure are configured to reflect the light emitted by the light-emitting structure;
wherein the grating structure is configured for polarization stabilization of the emitted light, and wherein the grating structure comprises or consists of a dielectric material.

13. The method according to claim 12,
wherein the substrate and the epitaxial layer are formed of the same material.

14. (canceled)

15. (canceled)

16. The surface emitter according to claim 3,
wherein a distance between two adjacent grating elements of the plurality of periodically arranged grating elements corresponds to an integer multiple of a quarter wavelength of the emitted light.

17. The surface emitter according to claim 3,
wherein the epitaxial layer has a defect density of less than 1·10⁹ cm⁻² in at least one surface region.

18. The surface emitter according to claim 3,
wherein the grating structure comprises a material whose refractive index is at least 0.1 greater than or less than a refractive index of the first mirror structure and/or the second mirror structure.

19. The surface emitter according to claim 3,
wherein the first mirror structure and the second mirror structure comprise a Bragg mirror respectively.
